(19) United States
(12) Patent Application Publication
(10) Pub. No.: US 2024/0125622 A1
(43) Pub. Date: Apr. 18, 2024

(54) METHODS FOR POWER SAVING MANAGEMENT OF SMART GAS METER BASED ON SMART GAS AND INTERNET OF THINGS (IOT) SYSTEMS

(71) Applicant: CHENGDU QINCHUAN IOT TECHNOLOGY CO., LTD., Chengdu (CN)

(72) Inventors: Zehua SHAO, Chengdu (CN); Yaqiang QUAN, Chengdu (CN); Junyan ZHOU, Chengdu (CN)

(73) Assignee: CHENGDU QINCHUAN IOT TECHNOLOGY CO., LTD., Chengdu (CN)

(21) Appl. No.: 18/398,083

(22) Filed: Dec. 27, 2023

(30) Foreign Application Priority Data
Nov. 9, 2023 (CN) 202311491522.1

(51) Int. Cl. G01D 4/02

(52) U.S. Cl. CPC G01D 4/02; G01D 2204/20

(57) ABSTRACT

The present disclosure discloses a method for power saving management of a smart gas meter based on smart gas and an Internet of Things system. The method includes: obtaining current power by a power detection unit; obtaining gas base data for of a preset time period from a built-in storage; sending the current power and the gas base data to a smart gas equipment management platform, and obtaining a recommended energy consumption interval of the smart gas meter and an expected usage frequency for a future time period of the smart gas meter from the smart gas equipment management platform; and determining data collection characteristics and data upload characteristics for the future time period based on the recommended energy consumption interval and the expected usage frequency; wherein the preset time interval is determined based on the current power.

### CROSS-REFERENCE TO RELATED APPLICATION

The application claims priority of Chinese Patent Application No. 202311491522.1, filed on Nov. 9, 2023, the entire contents of which are incorporated herein by reference.

### TECHNICAL FIELD

The present disclosure relates to the field of gas meter management, and in particular, to a method for power saving management of a smart gas meter based on smart gas and an Internet of Things (IoT) system.

### BACKGROUND

Smart gas meters are usually powered by batteries. When data communication is needed, IoT communication modules are activated to facilitate data exchange with data center of a gas company. However, when battery power is insufficient, a smart gas meter is unable to transmit data to the data center, resulting in the inability to record the data of the smart gas meter, which brings inconvenience to the use of the smart gas meter. Moreover, in situations where the battery power is low, the smart gas meter also faces the problem of ineffective valve closure, which compromises accurate measurement and gas safety.

In order to achieve energy-saving management of gas meters, a method for displaying a low-power smart gas meter is disclosed in CN106871983B. This existing technology uses multiple metering units to collect data and displays the data that meets the display criteria. However, this existing technology only considers reducing battery consumption by lowering the power used for displaying data on the LCD screen of the gas meter, without addressing power-saving management of the gas meter from a data processing perspective.

Therefore, it is desired to propose a method for power saving management of a smart gas meter based on smart gas and an Internet of Things (IoT) system to enable timely and effective formulation of power-saving strategies and realization of power-saving management for the smart gas meter.

### SUMMARY

One or more embodiments of the present disclosure provide a method for power saving management of a smart gas meter based on smart gas. The method is performed by a processor, and the processor is deployed inside the smart gas meter. The method includes: at each preset time interval, performing following steps including: obtaining current power by a power detection unit; obtaining gas base data of a preset time period from a built-in storage; sending the current power and the gas base data to a smart gas equipment management platform, and obtaining a recommended energy consumption interval of the smart gas meter and an expected usage frequency for a future time period of the smart gas meter from the smart gas equipment management platform; and determining data collection characteristics and data upload characteristics for the future time period based on the recommended energy consumption interval and the expected usage frequency; wherein the preset time interval is determined based on the current power.

One of the embodiments of the present disclosure provides an Internet of Things (IoT) system for power saving management of a smart gas meter based on smart gas. The IoT system includes a smart gas user platform, a smart gas service platform, a smart gas equipment management platform, a smart gas sensing network platform, and a smart gas object platform interacting in sequence; a processor is deployed inside the smart gas meter. The smart gas meter is deployed in the smart gas object platform, and the processor is configured to: obtaining current power by a power detection unit; obtaining gas base data of a preset time period from a built-in storage; sending the current power and the gas base data to a smart gas equipment management platform, and obtaining a recommended energy consumption interval of the smart gas meter and an expected usage frequency for a future time period of the smart gas meter from the smart gas equipment management platform; and determining data collection characteristics and data upload characteristics for the future time period based on the recommended energy consumption interval and the expected usage frequency; wherein the preset time interval is determined based on the current power.

One of the embodiments of the present disclosure provides a non-transitory computer-readable storage medium. The storage medium stores computer instructions, and when executed by a computer, the computer instructions cause the computer to implement the method for power saving management of a smart gas meter.

Some embodiments of the present disclosure include at least the following beneficial effect: by determining a recommended energy consumption interval and an expected usage frequency for a future time period based on gas base data and current power, then determining data collection characteristics, data upload characteristics, and data analysis characteristics for the future time period, power saving management can be performed accordingly, and energy consumption of the smart gas meter may be controlled more precisely, thereby extending the usage time of the smart gas meter.

### BRIEF DESCRIPTION OF THE DRAWINGS

The present disclosure is further described in terms of exemplary embodiments. These exemplary embodiments are described in detail with reference to the drawings. These embodiments are non-limiting exemplary embodiments, in which like reference numerals represent similar structures throughout the several views of the drawings, wherein:

FIG. 1 is a diagram of a platform structural of an Internet of Things (IoT) system for power saving management of a smart gas meter based on smart gas according to some embodiments of the present disclosure;

FIG. 2 is an exemplary flowchart of a method for power saving management of a smart gas meter based on smart gas according to some embodiments of the present disclosure;

FIG. 3 is an exemplary schematic diagram of a process for determining data analysis characteristics according to some embodiments of the present disclosure; and

FIG. 4 is an exemplary schematic diagram of a process for determining a target risk analysis result according to some embodiments of the present disclosure.

### DETAILED DESCRIPTION

In the following detailed description, numerous specific details are set forth by way of examples in order to provide a thorough understanding of the relevant disclosure. Obviously, drawings described below are only some examples or embodiments of the present disclosure. Those skilled in the art, without further creative efforts, may apply the present disclosure to other similar scenarios according to these drawings. It should be understood that the purposes of these illustrated embodiments are only provided to those skilled in the art to practice the application, and not intended to limit the scope of the present disclosure. Unless obviously obtained from the context or the context illustrates otherwise, the same numeral in the drawings refers to the same structure or operation.

It will be understood that the terms “system,” “device,” “unit,” and/or “module” used herein are one method to distinguish different components, elements, parts, sections, or assemblies of different levels in ascending order. However, the terms may be displaced by other expressions if they may achieve the same purpose.

The terminology used herein is for the purposes of describing particular examples and embodiments only and is not intended to be limiting. As used herein, the singular forms “a,” “an,” and “the” may be intended to include the plural forms as well, unless the context clearly indicates otherwise. It will be further understood that the terms “include” and/or “comprise,” when used in this disclosure, specify the presence of integers, devices, behaviors, stated features, steps, elements, operations, and/or components, but do not exclude the presence or addition of one or more other integers, devices, behaviors, features, steps, elements, operations, components, and/or groups thereof.

The flowcharts used in the present disclosure illustrate operations that systems implement according to some embodiments of the present disclosure. It is to be expressly understood, the operations of the flowcharts may be implemented not in order. Conversely, the operations may be implemented in an inverted order, or simultaneously. Moreover, one or more other operations may be added to the flowcharts. One or more operations may be removed from the flowcharts.

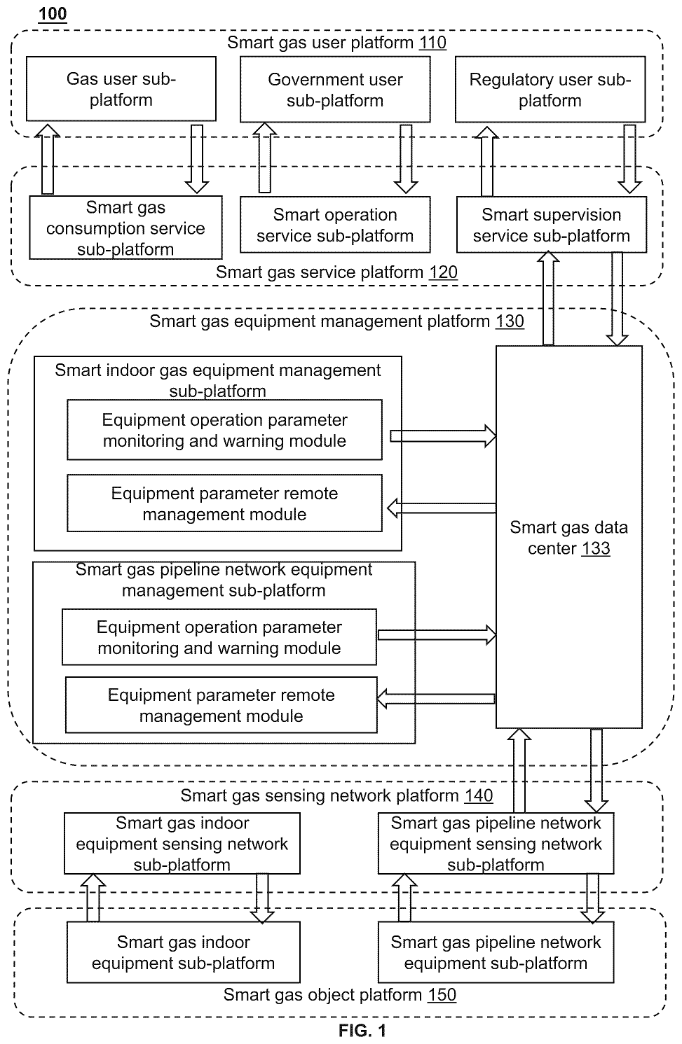

FIG. 1 is a diagram of a platform structural of an Internet of Things (IoT) system 100 for power saving management of a smart gas meter based on smart gas according to some embodiments of the present disclosure. The Internet of Things (IoT) system 100 for power saving management of a smart gas meter based on smart gas involved in the embodiments of the present disclosure is described in detail below. It should be noted that the following embodiments are used only for explaining the present disclosure and do not constitute a limitation of the present disclosure.

In some embodiments, the Internet of Things system 100 for power saving management of a smart gas meter based on smart gas (hereinafter referred to as the IoT system 100) may include a smart gas user platform 110, a smart gas service platform 120, a smart gas equipment management platform 130, a smart gas sensing network platform 140, and a smart gas object platform 150.

The smart gas user platform 110 is a platform for interacting with users. In some embodiments, the smart gas user platform 110 may be configured as a terminal device.

In some embodiments, the smart gas user platform 110 may include a gas user sub-platform, a government user sub-platform, and a regulatory user sub-platform.

The gas user sub-platform is a platform that provides gas users with data related to gas usage and solutions to gas problems. The gas users include industrial gas users, commercial gas users, and general gas users.

The government user sub-platform is a platform that provides data related to gas operation for government users. The government users include managers of gas operation entities (e.g., managers of an administration department) or the like.

The regulatory user sub-platform is a platform for regulating the operation of the entire IoT system 100. Regulatory users include personnel of a safety management department, etc.

In some embodiments, the smart gas user platform 110 may send query instructions for gas equipment parameter management information to the smart gas equipment management platform 130 through the smart gas service platform 120, and receive gas equipment management programs uploaded by the smart gas service platform 120.

The smart gas service platform 120 is a platform used to communicate the user's needs and control information. The smart gas service platform 120 may obtain gas equipment management information from the smart gas equipment management platform 130 and upload it to the smart gas user platform 110.

In some embodiments, the smart gas service platform 120 may include a smart gas consumption service sub-platform, a smart operation service sub-platform, and a smart supervision service sub-platform.

The smart gas consumption service sub-platform is a platform that provides gas services to gas users.

The smart operation service sub-platform is a platform that provides government users with information related to gas operation.

The smart supervision service sub-platform is a platform that provides supervisory needs for regulatory users.

In some embodiments, the smart gas service platform 120 may send the gas equipment management programs to the regulatory user sub-platform based on the smart supervision service sub-platform.

The smart gas equipment management platform 130 is a platform that integrates and coordinates the linkage and collaboration between various functional platforms, aggregates all the information of the Internet of Things (IoT), and provides perception management and control management functions for the IoT operation system.

In some embodiments, the smart gas equipment management platform 130 may include a smart indoor gas equipment management sub-platform, a smart gas pipeline network equipment management sub-platform, and a smart gas data center.

The smart indoor gas equipment management sub-platform is a platform for processing information related to indoor equipment. In some embodiments, the smart indoor gas equipment management sub-platform includes an equipment operation parameter monitoring and warning module and an equipment parameter remote management module. The smart indoor gas equipment management sub-platform may analyze and process information related to indoor equipment by means of the foregoing modules.

The smart gas pipeline network equipment management sub-platform is a platform for monitoring and managing pipeline network equipment. In some embodiments, the smart gas pipeline network equipment management sub-platform includes an equipment operation parameter monitoring and warning module and an equipment parameter remote management module. The smart gas pipeline network equipment management sub-platform may analyze and process information related to the pipeline network equipment by means of the foregoing modules.

A smart gas data center 133 may be used to store and manage all operation information of the IoT system 100. In some embodiments, the smart gas data center may be configured as a storage device for storing data related to gas equipment, etc.

In some embodiments, the smart gas equipment management platform 130 may interact with the smart gas service platform 120 and the smart gas sensing network platform 140, respectively, through the smart gas data center 133. For example, the smart gas data center may send gas equipment management information to the smart gas service platform 120. As another example, the smart gas data center may send the query instructions for the gas equipment parameter management information to the smart gas sensing network platform 140 to obtain the data related to gas equipment.

The smart gas sensing network platform 140 may be a functional platform for managing sensing communications. In some embodiments, the smart gas sensing network platform 140 may enable sensing information communication and controlling information communication.

In some embodiments, the smart gas sensing network platform 140 may include a smart gas indoor equipment sensing network sub-platform and a smart gas pipeline network equipment sensing network sub-platform, which may be used to obtain operation information of the indoor equipment and the pipeline network equipment, respectively.

The smart gas object platform 150 may be a functional platform for sensing information generation and controlling information execution.

In some embodiments, the smart gas object platform 150 may include a smart gas indoor equipment sub-platform and a smart gas pipeline network equipment sub-platform.

In some embodiments, the smart gas indoor equipment sub-platform may be configured for various types of indoor equipment of a gas customer. The indoor equipment may include a gas meter, an indoor gas pipeline, or the like.

In some embodiments, the smart gas pipeline network equipment sub-platform may be configured for various types of pipeline network equipment and monitoring equipment. The pipeline network equipment may include an outdoor gas pipeline, a valve control device, a gas storage tank, a pressure regulating device, or the like; and the monitoring equipment may include a gas flow meter, a pressure sensor, and a temperature sensor.

Some embodiments of the present disclosure, based on the IoT system 100, a closed loop of information operation between the smart gas object platform and the smart gas user platform can be formed, and coordinated and operated regularly under the unified management of the smart gas management platform, realizing the informatization and intelligence of power saving management of the smart gas meter.

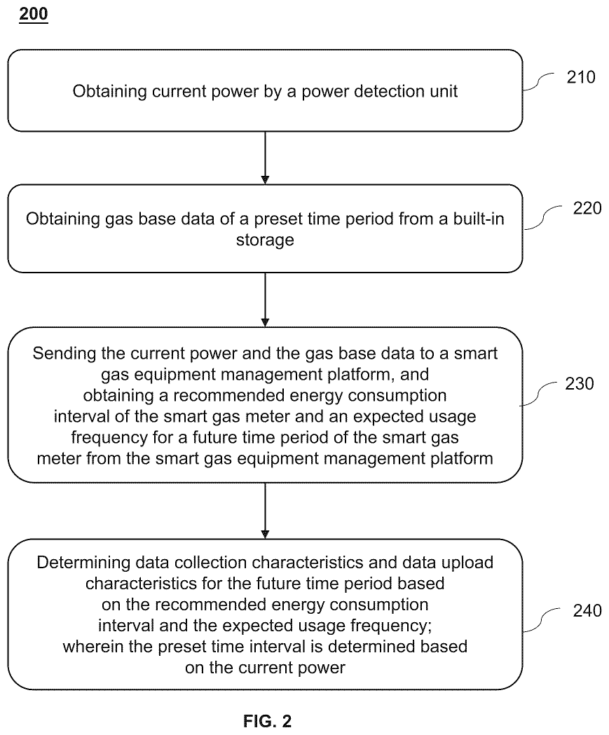

FIG. 2 is an exemplary flowchart of a method for power saving management of a smart gas meter based on smart gas according to some embodiments of the present disclosure. In some embodiments, process 200 may be executed by a processor.

The processor is deployed inside the smart gas meter, and the smart gas meter is deployed on the smart gas object platform. As shown in FIG. 2, the process 200 includes the following steps.

In some embodiments, the processor may perform steps 210-240 at each preset time interval.

In some embodiments, the preset time interval may be determined based on current power. In some embodiments, the processor may determine the preset time interval based on a corresponding relationship between different currents and different time intervals and the current power. The corresponding relationship between different currents and different time intervals may be preset based on prior knowledge or historical data. In some embodiments, the preset time interval is negatively correlated with the current power. The lower the current power, the longer the preset time interval.

By setting the preset time interval negatively correlated to the current power, energy consumption of the smart gas meter when executing steps 210-240 may be reduced, achieving the aim of power saving.

In step 210, the current power may be obtained by a power detection unit.

The power detection unit refers to a unit used to monitor the power of the smart gas meter. The power detection unit is deployed internally in the smart gas meter. For example, the power detection unit may be a Direct Current (DC) power sensor.

The current power refers to remaining power of the smart gas meter.

In some embodiments, at each preset time interval, the processor may obtain the current power of the smart gas meter through the power detection unit.

In step 220, gas base data of a preset time period is obtained from a built-in storage.

The built-in storage refers to a storage device configured in the smart gas object platform.

The preset time period refers to a predefined historical time period. In some embodiments, the preset time period may be a period of time prior to obtaining the current power. In some embodiments, the preset time period may be determined manually.

In some embodiments, the gas base data may include data such as gas usage data, gas consumption amount data, sound data, gas concentration data, gas temperature data, or the like. In some embodiments, the processor may retrieve the gas base data from the smart gas object platform.

The gas usage data refers to data related to gas usage, such as a gas usage frequency, a gas usage duration, etc. The gas usage data is obtained by the smart gas equipment management platform through interaction with a user terminal and is sent to the smart gas object platform.

The gas consumption amount data refers to an amount of gas consumption. The gas consumption amount data is recorded and uploaded to the smart gas object platform by the smart gas meter.

The sound data refers to data of sound at a gas usage site.

In step 230, the current power and the gas base data are sent to the smart gas equipment management platform, and a recommended energy consumption interval of the smart gas meter and an expected usage frequency for a future time period of the smart gas meter are obtained from the smart gas equipment management platform.

In some embodiments, the processor may send the current power and the gas base data to the smart gas equipment management platform via the smart gas sensing network platform. In some embodiments, the processor may send the current power amount and the gas base data to the smart gas data center via the smart gas indoor equipment sensing network sub-platform.

The recommended energy consumption interval refers to an interval used to limit the energy consumption of the smart gas meter.

The recommended energy consumption interval may be obtained by the smart gas equipment management platform and sent to the processor. In some embodiments, the smart gas equipment management platform may determine the recommended energy consumption interval based on the current power by querying an energy consumption interval lookup table. The energy consumption interval lookup table includes different reference energy consumption intervals corresponding to different reference power, and it may be constructed based on a situation of energy consumption and power usage of the smart gas meter in historical data.

The expected usage frequency refers to a predicted gas usage frequency by a user in the future time period. The future time period may be preset by the IoT system or by humans.

The expected usage frequency may be obtained by the smart gas equipment management platform and sent to the processor. In some embodiments, the smart gas equipment management platform may determine the expected usage frequency for the future time period based on the gas base data.

In some embodiments, the smart gas equipment management platform may determine the expected usage frequency for the future time period based on the gas usage data in the gas base data.

In some embodiments, the smart gas equipment management platform may determine the expected usage frequency for the future time period by a usage frequency prediction model. The usage frequency prediction model is a machine learning model, such as a deep neural network model.

In some embodiments, an input to the usage frequency prediction model includes a preset time period and time characteristics for the future time period, and an output includes the expected usage frequency for the future time period.

The time characteristics refer to characteristics related to a time period. For example, the time characteristics may include a duration and a start time of the future time period.

The usage frequency prediction model may be trained by the smart gas equipment management platform. In some embodiments, the usage frequency prediction model may be trained based on first training samples with first labels. For example, a plurality of first training samples with the first labels may be inputted into an initial usage frequency prediction model. A loss function may be constructed based on the first labels and outputs of the initial usage frequency prediction model. Parameters of the initial usage frequency prediction model may be iteratively updated based on the loss function. The model training is completed when the loss function of the initial usage frequency prediction model satisfies a certain predetermined condition, and then a trained usage frequency prediction model is obtained. The predetermined condition may include the convergence of the loss function, a count of iterations reaching a threshold, etc.

In some embodiments, each of the first training samples may include sample gas usage data for a sample first time period and sample time characteristics for a sample second time period. The first label may be a sample expected usage frequency for the sample second time period. The first training sample and the first label may be determined based on historical data. The sample first time period and the sample second time period both are historical time periods, with the sample second time period following the sample first time period.

In some embodiments of the present disclosure, determining the expected usage frequency and the recommended energy consumption interval for the future time period facilitates accurate analysis of data collection characteristics and data upload characteristics, thereby promoting more efficient operation of the smart gas meter and reducing energy consumption.

In step 240, the data collection characteristics and the data upload characteristics for the future time period are determined based on the recommended energy consumption interval and the expected usage frequency.

The data collection characteristics refer to characteristics related to the collection of the gas base data. For example, the data collection characteristics include a collection amount, a collection frequency, or the like.

In some embodiments, the data collection characteristics may include collection characteristics for different dimensions of gas base data. For example, the data collection characteristics may include a collection amount of the gas consumption amount data, a collection frequency of the gas consumption amount data, a collection amount of gas temperature data, a collection frequency of gas temperature data, or the like.

The data upload characteristics refer to characteristics related to the uploading of the gas base data. For example, the data upload characteristics include an upload amount, an upload frequency, or the like. Uploading refers to a process of uploading the gas base data from the smart gas object platform to the smart gas equipment management platform.

In some embodiments, the data upload characteristics may include upload characteristics for different dimensions of the gas base data. For example, the data upload characteristics may include an uploaded amount of the gas consumption amount data, an uploaded frequency of the gas consumption amount data, thane uploaded amount of the gas temperature data, an uploaded frequency of the gas temperature data, or the like.

The processor may determine the data collection characteristics and the data upload characteristics for the future time period in multiple ways. In some embodiments, the processor may first determine a plurality of optional first combinations based on the recommended energy consumption interval, each of the optional first combinations consists of a specific set of data collection characteristics and data upload characteristics; based on the expected usage frequency, select a target first combination from the plurality of optional first combinations to obtain the data collection characteristics and the data upload characteristics for the future time period. When the smart gas meter operates according to the first combination, the energy consumption is within the recommended energy consumption interval.

In some embodiments, the processor may pre-record and save energy consumption corresponding to different data collection characteristics and different data upload characteristics, respectively, based on historical data to obtain a lookup table. In some embodiments, the processor may determine the plurality of optional first combinations of data collection characteristics and data upload characteristics based on the recommended energy consumption interval, for example, by looking up a table.

In some embodiments, the processor may select the target first combination from the plurality of optional first combinations based on the expected usage frequency. For example, the greater the expected usage frequency, the greater the energy consumption of the target first combination that is selected from the plurality of optional first combinations. It should be noted that the greater the energy consumption of the smart gas meter, the greater the amount and frequency of data collection in the data collection characteristics at this time, and the greater the amount and frequency of data upload in the data upload characteristics.

In some embodiments, the processor may obtain a misjudgment rate for the future time period from the smart gas equipment management platform; and based on the recommended energy consumption interval, the expected usage frequency, and the misjudgment rate, determine the data collection characteristics and the data upload characteristics.

The misjudgment rate refers to a probability of error in determining whether there is a risk in the usage of gas.

For example, if there is no leakage in the gas pipeline, but the smart gas meter determines that a risk analysis result is 80% (indicating that the probability of there being a risk in the usage of gas is 80%), then the misjudgment rate is 80%. As another example, if there is a leakage in the gas pipeline but the smart gas meter determines that the risk analysis result is 20% (indicating that the probability of there being a risk in the usage of gas is 20%), then the misjudgment rate is 80%. See below for more information on the risk analysis result.

The misjudgment rate may be determined by the smart gas equipment management platform and sent to the processor. In some embodiments, the smart gas equipment management platform may determine a plurality of optional first combinations based on the recommended energy consumption interval; and for each optional first combination, the misjudgment rate for the future time period may be predicted based on data collection characteristics and data upload characteristics corresponding to the first combination, gas base data and an expected usage frequency during the predetermined time period.

In some embodiments, the smart gas equipment management platform may predict the misjudgment rate for the future time period using a misjudgment rate prediction model. The misjudgment rate prediction model is a machine learning model, such as a deep neural network model, etc.

In some embodiments, an input of the misjudgment rate prediction model includes the data collection characteristics, the data upload characteristics, and the gas base data for the predetermined time period, and the expected usage frequency for the future time period, and an output is the misjudgment rate for the future time period. For more description of the gas base data, see step 220 and its related description.

The misjudgment rate prediction model may be trained by the smart gas equipment management platform. In some embodiments, the smart gas equipment management platform may be trained based on a plurality of second training samples with second labels. The training process for the misjudgment rate prediction model is similar to the training process for the usage frequency prediction model, for more description, refer to step 230 and its related description.

In some embodiments, each of the second training samples may include sample data collection characteristics, sample data upload characteristics, and gas base data for a sample first time period, and a sample expected usage frequency for a second sample time period. The second label may be a misjudgment rate for the second sample time period. The second training sample may be determined based on historical data, and the second label may be determined based on the actual misjudgment rate (whether there is a misjudgment may be confirmed based on data traceability, on-site investigation, etc.). For more description of the first sample time period and the second sample time period, refer to step 230 and its related description.

In some embodiments, the processor may determine a plurality of optional first combinations based on the recommended energy consumption interval; for each of the optional first combinations, determine a misjudgment rate corresponding to the first combination based on the data collection characteristics, the data the upload characteristics, the expected usage frequency, and the gas base data corresponding to the first combination; and select the target first combination from the plurality of first combinations based on the misjudgment rates of the plurality of optional first combinations and a misjudgment threshold. In some embodiments, the processor may select a first combination corresponding to data collection characteristics and data upload characteristics with a misjudgment rate less than the misjudgment threshold as the target first combination to obtain the data collection characteristics and the data upload characteristics for the future time period.

In some embodiments of the present disclosure, the data collection characteristics and the data upload characteristics are determined based on the recommended energy consumption interval, the expected usage frequency, and the misjudgment rate, which is able to select combinations of data collection characteristics and data upload characteristics that have a low misjudgment rate so as to better meet the needs of power-saving power management and reduce the energy consumption.

In some embodiments, the processor may determine a target risk analysis result of the smart gas meter and a confidence level of the target risk analysis result; in response to the confidence level of the target risk analysis result below a first preset threshold, determine the data collection characteristics and the data upload characteristics based on the recommended energy consumption interval, the expected usage frequency, and the confidence level of the target risk analysis result.

The risk analysis result is a probability that there is a risk in the usage of gas. Situations where there is a risk in the usage of gas include gas theft, gas leakage, etc. The risk analysis result is determined by the smart gas meter.

The confidence level refers to a reliability of the risk analysis result.

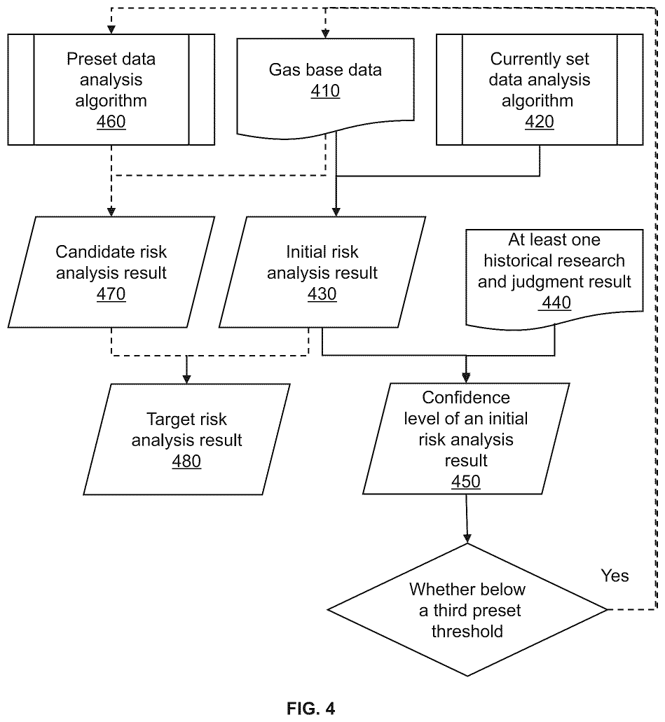

The target risk analysis result is a final risk analysis result. In some embodiments, the target risk analysis result is a risk analysis result that satisfies a specific confidence level condition. For example, the target risk analysis result may be a risk analysis result with a confidence level no lower than a third preset threshold. For more details about the third preset threshold, refer to FIG. 4 and its related description.

The processor may determine the target risk analysis result in various ways. In some embodiments, the processor may determine the target risk analysis result and its confidence level based on the gas base data for the preset time period through a data analysis algorithm. For example, the data analysis algorithm may include various types of factor scoring algorithms, quantitative assessment algorithms, or the like. For a more detailed description of determining the target risk analysis result, see FIG. 4 and its related content.

The first preset threshold is a confidence level threshold for determining whether or not to adjust the data collection characteristics and the data upload characteristics. In some embodiments, the first preset threshold may be determined by manual setting.

In some embodiments, the processor may determine initial data collection characteristics and initial data upload characteristics based on the recommended energy consumption interval and the expected usage frequency. See above for further descriptions relating to this embodiment.

In some embodiments, if the confidence level of the target risk analysis result is below the first preset threshold, the processor may adjust the initial data collection characteristics and the initial data upload characteristics based on the confidence level of the target risk analysis result.

In some embodiments, if the confidence level of the target risk analysis result is below the first preset threshold, the processor may increase the collection amount and the collection frequency in the initial data collection characteristics, and/or the upload amount, and the upload frequency in the initial data upload characteristics. In some embodiments, the increase amplitude may be negatively correlated with the confidence level.

In certain embodiments of the present disclosure, adjusting the data collection characteristics and the data upload characteristics based on the confidence level of the target risk analysis result may prevent insufficient discovery of various risks occurring during usage due to low collection and upload frequencies. If the confidence level of the risk analysis result is low, power saving alone cannot be considered, and in a short term, it is still necessary to collect data with a larger collection amount and a higher collection frequency, so as to allow the smart gas meter to perform the data analysis again to obtain analysis results with a higher confidence level.

In some embodiments, the processor may also determine data analysis characteristics for the future time period based on the recommended energy consumption interval and the expected usage frequency for the future time period.

The data analysis characteristics refer to characteristics related to the analysis on the gas base data.

In some embodiments, the data analysis characteristics include at least one real-selected analysis dimension and an amount of analyzed data for the at least one real-selected analysis dimension. In some embodiments, the data analysis characteristics further include the type of algorithm used in the data analysis. For a more detailed explanation of the data analysis algorithm, refer to FIG. 4 and its related description.

The real-selected analysis dimension is related to an actual risk analysis.

In some embodiments, the real-selected analysis dimension includes at least the gas consumption amount, the gas temperature, the gas concentration, and the image and the sound data of a site location of the smart gas meter. The image of the site location of the smart gas meter refers to an image of the installation location of the smart gas meter. For more information about the sound data, refer to step 220 and its related description.

The amount of analyzed data refers to an amount of data corresponding to the real-selected analysis dimension during actual analysis. For example, if the real-selected analysis dimension is the image of the site location and the gas consumption amount of the smart gas meter, the corresponding analysis data amount may be a count of frames of the image and a count of time points of the gas consumption amount.

The processor may determine the data analysis characteristics for the future time period in multiple ways. In some embodiments, the processor may first determine a plurality of optional second combinations based on the recommended energy consumption interval. Each of the optional second combinations consists of a set of specific data collection characteristics, the data upload characteristics, and the data analysis characteristics. Then, the processor may, based on the expected usage frequency, select a target second combination from the plurality of optional second combinations to obtain the data collection characteristics, the data upload characteristics, and the data analysis characteristics for the future time period. When the smart gas meter operates according to the second combination, its energy consumption is within the recommended energy consumption interval. The determination of the second combination and the target second combination is similar to the determination of the first combination and the target first combination, as described in detail in step 240 and its related description.

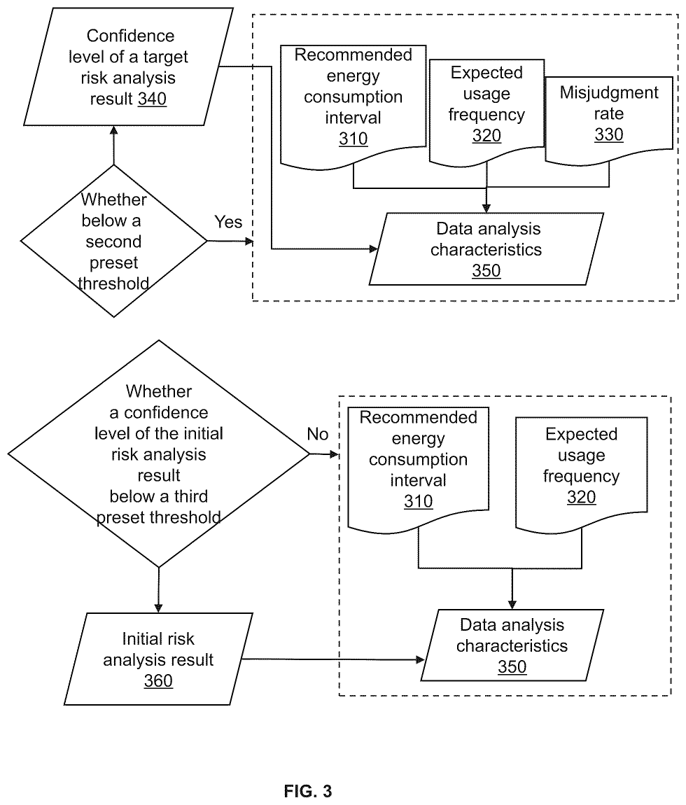

In some embodiments, the processor may determine the data analysis characteristic based on the recommended energy consumption interval, the expected usage frequency, and the misjudgment rate. For a more detailed description of this embodiment, see FIG. 3 and its related description.

In some embodiments of the present disclosure, the recommended energy consumption interval and the expected usage frequency for the future time period are determined based on the gas base data and the current power consumption, and then the data collection characteristics, the data upload characteristics, and the data analysis characteristics for the future time period may be determined to accordingly carry out power saving management to more accurately control the energy consumption of the smart gas meter, thereby extending the use time of the smart gas meter.

FIG. 3 is an exemplary schematic diagram of a process for determining data analysis characteristics according to some embodiments of the present disclosure.

In some embodiments, the processor may obtain a misjudgment rate 330 for a future time period from the smart gas equipment management platform; and determine data analysis characteristics 350 based on a recommended energy consumption interval 310, a expected usage frequency 320, and the misjudgment rate 330.

For more information about the misjudgment rate 330, refer to FIG. 2 and its corresponding description. It should be noted that when determining the misjudgment rate based on a misjudgment rate prediction model, an input may also include data analysis characteristics. Similarly, the second training sample also includes sample data analysis characteristics.

In some embodiments, the processor may determine a plurality of optional second combinations based on the recommended energy consumption interval 310; for each of the optional second combinations, determine the misjudgment rate 330 for the second combination based on the data collection characteristics, data upload characteristics, data analysis characteristics 350, and the expected usage frequency 320 of gas base data corresponding to the second combination; and select a target second combination from the plurality of second combinations based on the misjudgment rate 330 and a misjudgment threshold. In some embodiments, the processor may choose a second combination corresponding to data collection characteristics, data upload characteristics, and data analysis characteristics with a misjudgment rate lower than the misjudgment threshold as the target second combination, and then obtain the data collection characteristics, the data upload characteristics, and the data analysis characteristics 350 for the future time period. It should be noted that the misjudgment threshold used to determine the target first combination and the target second combination may be the same or different.

In some embodiments of the present disclosure, the data analysis characteristics may be determined based on the recommended energy consumption interval, the expected usage frequency, and the misjudgment rate, which allows for the selection of a combination of the data collection characteristics, the data upload characteristics, and the data analysis characteristics with a low misjudgment rate, thereby fulfilling the requirements of power-saving management and reducing energy consumption more effectively.

In some embodiments, the processor may determine the target risk analysis result of the smart gas meter and the confidence level of the target risk analysis result; and in response to a confidence level of the target risk analysis result 340 below a second preset threshold, determine the data analysis characteristics 350 based on the recommended energy consumption interval 310, the expected usage frequency 320, the misjudgment rate 330, and the confidence level of the target risk analysis result 340. For more detailed information about the target risk analysis result, please refer to FIG. 2, FIG. 4, and related content thereof.

The second preset threshold refers to a confidence level threshold used to determine whether to adjust the data analysis characteristics. In some embodiments, the second preset threshold may be manually set.

In some embodiments, the processor may determine initial data analysis characteristics based on the recommended energy consumption interval 310, the expected usage frequency 320, and the misjudgment rate 330.

In some embodiments, if the confidence level of the target risk analysis result 340 is below the second preset threshold, the processor may adjust the initial data analysis characteristics. For example, the processor may increase a real-selected analysis dimension and an amount of analyzed data for the real-selected analysis dimension in the initial data analysis characteristics as the final data analysis characteristics 350.

In some embodiments of the present disclosure, adjusting the data analysis characteristics based on the confidence level of the target risk analysis results can avoid insufficient identification of various risks that occur during usage due to the selection of too few real-selected analysis dimensions or too little analyzed data.

In some embodiments, the processor may perform a risk analysis on the gas base data of the preset time period using a currently set data analysis algorithm to determine an initial risk analysis result 360 of the smart gas meter; and determine the data analysis characteristics 350 based on the initial risk analysis result 360, the recommended energy consumption interval 310, and the expected usage frequency 320.

For a more detailed description of the data analysis algorithm and the initial risk analysis result, please refer to FIG. 4 and its related content.

In some embodiments, the processor may determine the data analysis characteristics 350 based on the initial risk analysis result 360, the recommended energy consumption interval 310, and the expected usage frequency 320.

In some embodiments, the processor may determine initial data analysis characteristics based on the recommended energy consumption interval 310 and the expected usage frequency 320. For more information on the determination of the data analysis characteristics based on the recommended energy consumption interval and the expected usage frequency, please refer to FIG. 2 and its related description.

In some embodiments, in response to that a confidence level of an initial risk analysis result 360 is no lower than a third preset threshold and the probability of the initial risk analysis result 360 is located between a first probability threshold and a second probability threshold, the processor may adjust the initial data analysis characteristics. For example, the processor may increase the real-selected analysis dimension and the amount of analyzed data for the real-selected analysis dimension in the initial data analysis characteristics, and select an algorithm with a higher energy consumption and higher predictive accuracy as the final data analysis characteristics.

In some embodiments, in response to that the confidence level of the initial risk analysis result 360 is below the third preset threshold, the processor may determine the target risk analysis result and adjust the initial data analysis characteristics based on the target risk analysis result. In some embodiments, the processor may adjust the initial data analysis characteristics when the probability of the target risk analysis result is located between the first probability threshold and the second probability threshold.

The adjustment manner is the same as that in the above embodiments. For more information on the target risk analysis result, please refer to FIG. 4 and its related description.

Some embodiments of the present disclosure determine the data analysis characteristics based on the initial risk analysis result, the recommended energy consumption interval, and the expected usage frequency, which can reduce power consumption while ensuring that the data analysis confidence level meets usage requirements.

FIG. 4 is an exemplary schematic diagram of a process for determining a target risk analysis result according to some embodiments of the present disclosure.

In some embodiments, the processor may perform a risk analysis on gas base data 410 for a preset time period using a currently set data analysis algorithm 420, and determine an initial risk analysis result 430 for a smart gas meter.

A data analysis algorithm refers to a related algorithm used for the risk analysis. For example, data analysis algorithms may include a fitting analysis algorithm, a model-based analysis algorithm, or the like. In some embodiments, multiple data analysis algorithms may be pre-stored in the smart gas meter.

The initial risk analysis result 430 refers to a preliminary determined risk analysis result. For more details on the risk analysis results, refer to FIG. 2 and its related description.

In some embodiments, the processor may determine the initial risk analysis result 430 in various ways. For example, if the currently set data analysis algorithm is a fitting analysis algorithm, the processor may fit gas base data, compare a fitting result with data in the standard database, and determine a reference the risk analysis result corresponding to reference gas base data similar to the fitting result as the initial risk analysis results 430. Different reference risk analysis results corresponding to different reference gas base data are recorded and stored in the standard database, and the standard database may be constructed based on historical data. For example, if the currently set data analysis algorithm is a model-based analysis algorithm, the processor may input the gas base data into an analysis model, and the analysis model may output the initial risk analysis result 430. The analysis model may be a machine learning model, such as a deep neural network model.

The analysis model may be trained using a plurality of third training samples with third labels. The training process for the analysis model is similar to that of the usage frequency prediction model, as shown in FIG. 2 and its related content.

In some embodiments, each of the third training samples may include sample gas base data, and the third label may be a sample risk analysis result. The third training sample may be determined based on historical data, and the third label may be obtained by manual labeling.

In some embodiments, the processor may obtain at least one historical research and judgment result 440 of the gas base data 410 from the smart gas equipment management platform, where the gas base data is uploaded by the smart gas meter to the smart gas equipment management platform; and based on the at least one the historical research and judgment result 440 and the initial risk analysis result 430 of the smart gas meter, determine a confidence level of an initial risk analysis result 450.

The historical research and judgment result 440 refers to a risk analysis result determined by history. In some embodiments, the historical research and judgment result 440 may be determined by the smart gas equipment management platform. In some embodiments, the historical research and judgment result 440 may be determined by the smart gas meter.

In some embodiments, the processor may weight a probability of the at least one historical research and judgment result with a probability of the initial risk analysis result of a current smart gas meter, and determine a weighted sum as the confidence level of the initial risk analysis result 450. The weights may be set in advance. For example, the historical research and judgment result determined by the smart gas equipment management platform may have a higher weight, while the historical research and judgment result and the initial risk analysis result of the smart gas meter have a lower weight.

In some embodiments, the processor may determine whether to adjust to a more complex, computationally intensive, and accurate data analysis algorithm based on a confidence level of the initial risk analysis result and the third preset threshold.

In some embodiments, if the confidence level of the initial risk analysis result is not lower than the third preset threshold, the processor may determine the initial risk analysis result as the target risk analysis result.

In some embodiments, the processor may perform a risk analysis on the gas base data 410 using at least one preset data analysis algorithm 460, respectively, to determine at least one candidate risk analysis result 470 when the confidence level of the initial risk analysis result is below the third preset threshold; and determine a target risk analysis result 480 by updating the initial risk analysis result 430 based on the at least one candidate risk analysis result 470.

The third preset threshold is a confidence level threshold used to determine whether or not to update the risk analysis result. In some embodiments, the third preset threshold may be manually set.

The preset data analysis algorithm 460 refers to a data analysis algorithm that is pre-existing in the smart gas meter.

The candidate risk analysis result 470 is a risk analysis result that is determined based on other data analysis algorithms different from the current data analysis algorithm.

In some embodiments, the processor may perform the risk analysis on the gas base data using at least one different preset data analysis algorithm to determine the at least one the candidate risk analysis result 470, respectively. For the content of how the data analysis algorithm performs the risk analysis, refer to above content.

The target risk analysis result 480 is a final risk analysis result. In some embodiments, the processor may determine an average of the at least one candidate risk analysis result 470 as the target risk analysis result 480.

In some embodiments, the processor may determine a non-outlier analysis result among the at least one the candidate risk analysis result 470 according to a preset probability threshold; and weighting the non-outlier analysis result to determine the target risk analysis result 480.

The preset probability threshold is a probability threshold used to determine the non-outlier analysis result. In some embodiments, the preset probability threshold may be determined based on the data collection characteristics employed at a current moment and the misjudgment rate corresponding to the data upload characteristics. For example, the preset probability threshold is negatively correlated with the misjudgment rate. For further description of the misjudgment rate, please refer to FIG. 2 and its relevant content.

In some embodiments, the processor may determine probability differences of at least one candidate risk analysis result 470 to other risk analysis results and determine an average value of the probability differences. The processor may determine a candidate risk analysis result 470 corresponding to an average value not greater than a preset probability threshold as the non-outlier analysis result.

For further description of the data collection characteristics, the data upload characteristics, and the misjudgment rate, please refer to FIG. 2 and its relevant content.

In some embodiments, the processor may determine the target risk analysis result by weighting non-outlier analysis results. The weights are positively correlated with the energy consumption of the data analysis algorithm corresponding to the at least one the candidate risk analysis result 470. Wherein the energy consumption of the data analysis algorithm is a power consumption rate or incremental increase when the processor runs a specific data analysis algorithm.

In some embodiments of the present disclosure, the target risk analysis result is determined by weighting the non-outlier analysis results. The higher the energy consumption of the preset data analysis algorithm, the higher the confidence level of the risk analysis result determined by the algorithm, thereby enabling an accurate determination of the target risk analysis result.

In some embodiments, after determining the target risk analysis result, the processor may determine the data analysis characteristics based on the target risk analysis results, the recommended energy consumption interval, and the expected usage frequency. The process of “determining the data analysis characteristics based on the target risk analysis result, the recommended energy consumption interval, and the expected usage frequency” is similar to the process of “determining the data collection characteristics and the data upload characteristics based on the recommended energy consumption interval, the expected usage frequency, and the confidence level of the risk analysis result”, which is described in FIG. 2 and its relevant content.

Some embodiments of the present disclosure perform the risk analysis on the gas base data using the at least one preset data analysis algorithm and determine the target risk analysis result based on at least one candidate risk analysis result, which can combine the advantages of multiple algorithms, improve the accuracy and reliability of risk analysis, and provide a better support for energy consumption reduction and safety management of the smart gas meter.

Embodiments of the present disclosure also provide a non-transitory computer-readable storage medium. The storage medium stores computer instructions, and when executed by a computer, the computer instructions cause the computer to implement the method for power saving management of a smart gas meter described in any of the above embodiments.

Having thus described the basic concepts, it may be rather apparent to those skilled in the art after reading this detailed disclosure that the foregoing detailed disclosure is intended to be presented by way of example only and is not limiting. Various alterations, improvements, and modifications may occur and are intended to those skilled in the art, though not expressly stated herein. These alterations, improvements, and modifications are intended to be suggested by this disclosure and are within the spirit and scope of the exemplary embodiments of this disclosure.

Moreover, certain terminology has been used to describe embodiments of the present disclosure. For example, the terms “one embodiment,” “an embodiment,” and “some embodiments” mean that a particular feature, structure, or characteristic described in connection with the embodiment is included in at least one embodiment of the present disclosure. Therefore, it is emphasized and should be appreciated that two or more references to “an embodiment” or “one embodiment” or “an alternative embodiment” in various portions of this specification are not necessarily all referring to the same embodiment. Furthermore, the particular features, structures, or characteristics may be combined as suitable in one or more embodiments of the present disclosure.

Furthermore, the recited order of processing elements or sequences, or the use of numbers, letters, or other designations therefore, is not intended to limit the claimed processes and methods to any order except as may be specified in the claims. Although the above disclosure discusses through various examples what is currently considered to be a variety of useful embodiments of the disclosure, it is to be understood that such detail is solely for that purpose and that the appended claims are not limited to the disclosed embodiments, but, on the contrary, are intended to cover modifications and equivalent arrangements that are within the spirit and scope of the disclosed embodiments. For example, although the implementation of various components described above may be embodied in a hardware device, it may also be implemented as a software only solution, e.g., an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. This method of disclosure, however, is not to be interpreted as reflecting an intention that the claimed subject matter requires more features than are expressly recited in each claim. Rather, claimed subject matter may lie in less than all features of a single foregoing disclosed embodiment.

In some embodiments, numbers describing the number of ingredients and attributes are used. It should be understood that such numbers used for the description of the embodiments use the modifier “about”, “approximately”, or “substantially” in some examples. Unless otherwise stated, “about”, “approximately”, or “substantially” indicates that the number is allowed to vary by ±20%. Correspondingly, in some embodiments, the numerical parameters used in the description and claims are approximate values, and the approximate values may be changed according to the required characteristics of individual embodiments. In some embodiments, the numerical parameters should consider the prescribed effective digits and adopt the method of general digit retention. Although the numerical ranges and parameters used to confirm the breadth of the range in some embodiments of the present disclosure are approximate values, in specific embodiments, settings of such numerical values are as accurate as possible within a feasible range.

For each patent, patent application, patent application publication, or other materials cited in the present disclosure, such as articles, books, specifications, publications, documents, or the like, the entire contents of which are hereby incorporated into the present disclosure as a reference. The application history documents that are inconsistent or conflict with the content of the present disclosure are excluded, and the documents that restrict the broadest scope of the claims of the present disclosure (currently or later attached to the present disclosure) are also excluded. It should be noted that if there is any inconsistency or conflict between the description, definition, and/or use of terms in the auxiliary materials of the present disclosure and the content of the present disclosure, the description, definition, and/or use of terms in the present disclosure is subject to the present disclosure.

Finally, it should be understood that the embodiments described in the present disclosure are only used to illustrate the principles of the embodiments of the present disclosure. Other variations may also fall within the scope of the present disclosure. Therefore, as an example and not a limitation, alternative configurations of the embodiments of the present disclosure may be regarded as consistent with the teaching of the present disclosure. Accordingly, the embodiments of the present disclosure are not limited to the embodiments introduced and described in the present disclosure explicitly.

What is claimed is:

1. A method for power saving management of a smart gas meter based on smart gas, executed by a processor, wherein the processor is deployed inside the smart gas meter, the method comprising:
at each preset time interval, performing following steps including:
obtaining current power by a power detection unit;
obtaining gas base data of a preset time period from a built-in storage;
sending the current power and the gas base data to a smart gas equipment management platform, and obtaining a recommended energy consumption interval of the smart gas meter and an expected usage frequency for a future time period of the smart gas meter from the smart gas equipment management platform; and
determining data collection characteristics and data upload characteristics for the future time period based on the recommended energy consumption interval and the expected usage frequency; wherein the preset time interval is determined based on the current power.

2. The method of claim 1, wherein the determining data collection characteristics and data upload characteristics for the future time period based on the recommended energy consumption interval and the expected usage frequency includes:
obtaining a misjudgment rate for the future time period from the smart gas equipment management platform; and
determining the data collection characteristics and the data upload characteristics based on the recommended energy consumption interval, the expected usage frequency, and the misjudgment rate.

3. The method of claim 1, wherein the determining data collection characteristics and data upload characteristics for the future time period based on the recommended energy consumption interval and the expected usage frequency includes:
determining a target risk analysis result of the smart gas meter and a confidence level of the target risk analysis result; and
in response to the confidence level of the target risk analysis result below a first preset threshold, determining the data collection characteristics and the data upload characteristics based on the recommended energy consumption interval, the expected usage frequency, and the confidence level of the target risk analysis result.

4. The method of claim 1, further comprising:
determining data analysis characteristics for the future time period based on the recommended energy consumption interval and the expected usage frequency; the data analysis characteristics including at least one real-selected analysis dimension and an amount of analyzed data for the at least one real-selected analysis dimension; the real-selected analysis dimension including at least a gas consumption amount, a gas temperature, a gas concentration, an image of a site location of the smart gas meter, and sound data.

5. The method of claim 4, wherein the determining the data analysis characteristics for the future time period based on the recommended energy consumption interval and the expected usage frequency includes:
obtaining a misjudgment rate for the future time period from the smart gas equipment management platform; and
determining the data analysis characteristics based on the recommended energy consumption interval, the expected usage frequency, and the misjudgment rate.

6. The method of claim 5, wherein the determining the data analysis characteristics based on the recommended energy consumption interval, the expected usage frequency, and the misjudgment rate includes:
determining a target risk analysis result of the smart gas meter and a confidence level of the target risk analysis result; and
in response to the confidence level of the target risk analysis result below a second preset threshold, determining the data analysis characteristics based on the recommended energy consumption interval, the expected usage frequency, the misjudgment rate, and the confidence level of the target risk analysis result.

7. The method of claim 4, wherein the determining the data analysis characteristics for the future time period based on the recommended energy consumption interval and the expected usage frequency includes:
determining an initial risk analysis result of the smart gas meter by performing a risk analysis on the gas base data of the preset time period using a currently set data analysis algorithm; and
determining the data analysis characteristics based on the initial risk analysis result, the recommended energy consumption interval, and the expected usage frequency.

8. The method of claim 7, further comprising:
obtaining at least one historical research and judgment result of the gas base data from the smart gas equipment management platform, the gas base data being uploaded to the smart gas equipment management platform by the smart gas meter; and
determining a confidence level of the initial risk analysis result based on the at least one historical research and judgment result and the initial risk analysis result of the smart gas meter.

9. The method of claim 7, further comprising:
in response to a confidence level of the initial risk analysis result below a third preset threshold, separately performing a risk analysis on the gas base data using at least one preset data analysis algorithm to determine at least one candidate risk analysis result; and
updating the initial risk analysis result based on the at least one candidate risk analysis result to determine a target risk analysis result.

10. The method of claim 9, wherein the updating the initial risk analysis result based on the at least one candidate risk analysis result to determine a target risk analysis result includes:
determining a non-outlier analysis result among the at least one candidate risk analysis result according to a preset probability threshold, the preset probability threshold being determined based on data collection characteristics and a misjudgment rate corresponding to data upload characteristics used at a current moment; and
weighting the non-outlier analysis result to determine the target risk analysis result, the weight being related to energy consumption of a data analysis algorithm corresponding to the at least one candidate risk analysis result.

11. An Internet of Things (IoT) system for power saving management of a smart gas meter based on smart gas, wherein the IoT system comprises a smart gas user platform, a smart gas service platform, a smart gas equipment management platform, a smart gas sensing network platform, and a smart gas object platform interacting in sequence; a processor is deployed inside the smart gas meter, the smart gas meter is deployed in the smart gas object platform, and the processor is configured to:
at each preset time interval, perform following steps including:
obtaining current power by a power detection unit;
obtaining gas base data of a preset time period from a built-in storage;
sending the current power and the gas base data to the smart gas equipment management platform, and obtaining a recommended energy consumption interval of the smart gas meter and an expected usage frequency for a future time period of the smart gas meter from the smart gas equipment management platform; and
determining data collection characteristics and data upload characteristics for the future time period based on the recommended energy consumption interval and the expected usage frequency; wherein the preset time interval is determined based on the current power.

12. The IoT system of claim 11, wherein the processor is configured to:
obtain a misjudgment rate for the future time period from the smart gas equipment management platform; and
determine the data collection characteristics and the data upload characteristics based on the recommended energy consumption interval, the expected usage frequency, and the misjudgment rate.

13. The IoT system of claim 11, wherein the processor is configured to:
determine a target risk analysis result of the smart gas meter and a confidence level of the target risk analysis result; and
in response to the confidence level of the target risk analysis result below a first preset threshold, determine the data collection characteristics and the data upload characteristics based on the recommended energy consumption interval, the expected usage frequency, and the confidence level of the target risk analysis result.

14. The IoT system of claim 11, wherein the processor is configured to:
determine data analysis characteristics for the future time period based on the recommended energy consumption interval and the expected usage frequency; the data analysis characteristics including at least one real-selected analysis dimension and an amount of analyzed data for the at least one real-selected analysis dimension; the real-selected analysis dimension including at least a gas consumption amount, a gas temperature, a gas concentration, an image of a site location of the smart gas meter, and sound data.

15. The IoT system of claim 14, wherein the processor is configured to:
obtain a misjudgment rate for the future time period from the smart gas equipment management platform; and
determine the data analysis characteristics based on the recommended energy consumption interval, the expected usage frequency, and the misjudgment rate.

16. The IoT system of claim 15, wherein the processor is configured to:
determine a target risk analysis result of the smart gas meter and a confidence level of the target risk analysis result; and
in response to the confidence level of the target risk analysis result below a second preset threshold, determine the data analysis characteristics based on the recommended energy consumption interval, the expected usage frequency, the misjudgment rate, and the confidence level of the target risk analysis result.

17. The IoT system of claim 14, wherein the processor is configured to:
determine an initial risk analysis result of the smart gas meter by performing a risk analysis on the gas base data of the preset time period using a currently set data analysis algorithm; and
determine the data analysis characteristics based on the initial risk analysis result, the recommended energy consumption interval, and the expected usage frequency.

18. The IoT system of claim 17, wherein the processor is configured to:
obtain at least one historical research and judgment result of the gas base data from the smart gas equipment management platform, the gas base data being uploaded to the smart gas equipment management platform by the smart gas meter; and
determine a confidence level of the initial risk analysis result based on the at least one historical research and judgment result and the initial risk analysis result of the smart gas meter.

19. The IoT system of claim 17, wherein the processor is configured to:
in response to a confidence level of the initial risk analysis result being below a third preset threshold, separately perform a risk analysis on the gas base data using at least one preset data analysis algorithm to determine at least one candidate risk analysis result; and
update the initial risk analysis result based on the at least one candidate risk analysis result to determine a target risk analysis result.

20. A non-transitory computer-readable storage medium storing computer instructions, when executed by a computer, the computer instructions cause the computer to implement the method for power saving management of a smart gas meter of claim 1.
